(19) United States
(12) Patent Application Publication
(10) Pub. No.: US 2014/0193984 A1
(43) Pub. Date: Jul. 10, 2014

(54) APPARATUS AND METHOD FOR REDUCING RESIDUAL STRESS OF SEMICONDUCTOR

(71) Applicant: SAMSUNG ELECTRONICS CO., LTD., Suwon-Si (KR)

(72) Inventors: Jae Dong PARK, Cheonan-si (KR); Hak Sung KIM, Seoul (KR); Jeong Sam LEE, Cheonan-si (KR); Eun Beom JEON, Wonju-si (KR); Ho-Tae JIN, Cheonan-si (KR)

(73) Assignees: Industry-University Cooperation Foundation Hanyang University, Seoul (KR); SAMSUNG ELECTRONICS CO., LTD., Suwon-Si (KR)

(21) Appl. No.: 14/143,759

(22) Filed: Dec. 30, 2013

(30) Foreign Application Priority Data
Jan. 10, 2013 (KR) 10-2013-0003118

(51) Int. Cl. H01L 21/67; H01L 21/263

(52) U.S. Cl. CPC H01L 21/67115; H01L 21/2636
USPC 438/795; 392/412; 392/420

(57) ABSTRACT

An apparatus for reducing residual stress of a semiconductor includes a stage configured to support a semiconductor wafer having the residual stress generated by a semiconductor manufacturing process. The apparatus includes an intense pulsed light (IPL) irradiation unit configured to irradiate IPL to the semiconductor wafer to reduce the residual stress of the semiconductor wafer, the IPL radiation unit being separated from the stage. The apparatus further includes at least one alignment unit configured to adjust relative positions of the stage and the IPL irradiation unit.

### CROSS-REFERENCE TO RELATED APPLICATIONS

This application claims the benefit of Korean Patent Application No. 10-2013-0003118, filed on Jan. 10, 2013, in the Korean Intellectual Property Office, the disclosure of which is incorporated herein in its entirety by reference.

### BACKGROUND

The inventive concepts relate to an apparatus and/or method for reducing residual stress of a semiconductor, and more particularly, to an apparatus and/or method for reducing residual stress of a semiconductor which may reduce residual stress generated in a semiconductor manufacturing process by an intense pulsed light (IPL) annealing method.

During a semiconductor manufacturing process, semiconductor devices and circuits are deposited on a semiconductor wafer, for example, a silicon substrate, at a high temperature of 500° C. or higher. After the deposition process, residual stress due to heat is generated in the semiconductor wafer at room temperature because of a difference in the thermal expansion coefficient between elements of the silicon substrate.

Also, a packaging process is performed after the deposition process. During the packaging process, a wafer thinning process is performed on the semiconductor wafer by grinding a rear surface of the semiconductor wafer and polishing the semiconductor wafer.

During the grinding process, mechanical residual stress is generated by a shear force generated between a wafer and a grinding wheel. During the polishing process, mechanical residual stress is generated by a shear force generated between a wafer and a polishing pad.

These residual stresses increase a possibility of damage because the residual stress weakens the strength of a semiconductor wafer. Accordingly, reducing residual stress on the semiconductor wafer reduces the possibility of damage to the semiconductor wafer.

To reduce the residual stress, a method for heat treating a semiconductor wafer in a high temperature environment has been considered. See Korean Patent No. 10-1062481 (2011.08.30.), the entire contents of which are incorporated herein by reference.

When a semiconductor wafer is maintained for a long time at high temperature in a state where tensile stress and compressive stress are applied between electrical elements and a silicon substrate or within the silicon substrate, the residual stress may be reduced due to plastic deformation caused by creep.

However, since the wafer is to be exposed at a high temperature for a long time, the method for reducing residual stress by the high temperature annealing method is difficult to apply to a manufacturing line for mass production. Also, the long-time exposure at a high temperature may cause deformation of an electrical element and, thus, the residual stress may not be completely removed.

Furthermore, as the thickness of a semiconductor wafer decreases, a flexural phenomenon more frequently occurs at a high temperature after the deposition process of electrical elements. Thus, the residual stress reduction method using a high temperature annealing method has a limit in reducing residual stress.

### SUMMARY

The inventive concepts provide an apparatus and/or method for reducing residual stress of a semiconductor which may reduce residual stress remaining in the semiconductor at room temperature and/or in an atmospheric condition, decrease a possibility of deformation of an element, and/or reduce the residual stress in a short time, thereby improving fracture strength of the semiconductor.

According to at least one example embodiment, an apparatus for reducing residual stress of a semiconductor includes a stage configured to support a semiconductor wafer having the residual stress generated by a semiconductor manufacturing process. The apparatus includes an intense pulsed light (IPL) irradiation unit configured to irradiate IPL to the semiconductor wafer to reduce the residual stress of the semiconductor wafer. The IPL radiation unit may be separated from the stage. The apparatus further includes at least one alignment unit configured to adjust relative positions of the stage and the IPL irradiation unit.

According to at least one example embodiment, the IPL irradiation unit includes at least one lamp module irradiating IPL and a light wavelength filter disposed between the lamp model and the stage and configured to selectively filter light of a desired wavelength band from the IPL irradiated by the lamp module. The IPL irradiation unit further includes a beam guide disposed between the light wavelength filter and the stage and configured to guide light passing through the light wavelength filter toward the semiconductor wafer. The IPL irradiation unit further includes an IPL control unit connected to the lamp module and configured to control generation of IPL of the lamp module.

According to at least one example embodiment, the lamp module includes a lamp housing having a shape capable of containing gas, an electrode disposed at each opposite end of the lamp housing, and a reflective mirror disposed outside the lamp housing.

According to at least one example embodiment, the IPL control unit includes a high voltage power generator configured to apply a voltage to the electrode and a capacitor configured to store charges and apply the stored charges to the electrode. The IPL control unit further includes a triggering/control circuit configured to control an operation of the high voltage power generator and an operation of applying the charges stored in the capacitor to the electrode.

According to at least one example embodiment, the apparatus further includes a cooling unit configured to remove heat generated in the IPL irradiation unit. The cooling unit includes a lamp cooling unit forming a space in which a supplied coolant is movable in order to cool the IPL irradiation unit using the coolant, and a coolant flow pipe connected to the lamp cooling unit, through which the coolant circulates.

According to at least one example embodiment, the at least one alignment unit includes a horizontal moving unit coupled to the stage and configured to horizontally move the stage, and a distance adjustment unit coupled to the IPL irradiation unit and configured to adjust a relative vertical distance between the stage and the IPL irradiation unit.

According to at least one example embodiment, the semiconductor process is at least one of a grinding process and a polishing process for thinning of the semiconductor wafer.

According to at least one example embodiment, a method for reducing residual stress of a semiconductor includes setting a position of a semiconductor wafer having the residual stress generated by a semiconductor manufacturing process, setting an intense pulsed light (IPL) irradiation pattern of an IPL irradiation unit, and irradiating the IPL according to the IPL irradiation pattern using the IPL irradiating unit.

According to at least one example embodiment, the setting of a position of the semiconductor wafer includes horizontally moving the semiconductor wafer to be located under the IPL irradiation unit, and adjusting a relative vertical distance between the semiconductor wafer and the IPL irradiation unit.

According to at least one example embodiment, the setting of an IPL irradiation pattern includes setting an intensity of IPL, setting a pulse width of IPL, setting a pulse gap of IPL, and setting a pulse number of IPL.

According to at least one example embodiment, the setting an intensity of IPL sets the intensity of IPL in a range of 0.01 J/cm²˜100 J/cm².

According to at least one example embodiment, the setting of a pulse width of IPL sets the pulse width of IPL in a range of 0.1 ms˜100 ms.

According to at least one example embodiment, the setting of a pulse gap of IPL sets the pulse gap of IPL in a range of 0.1 ms˜100 ms.

According to at least one example embodiment, the setting of a pulse number of IPL sets the pulse number of IPL in a range of 1˜1000 times.

According to at least one example embodiment, the method further includes performing at least one of grinding and polishing the semiconductor wafer prior to the setting a position of the semiconductor wafer.

According to at least one example embodiment, an apparatus includes a movable stage configured to support a semiconductor wafer having residual stress caused by at least one semiconductor manufacturing process, the movable stage being configured to move in a first plane. The apparatus further includes a movable intense pulsed light (IPL) irradiation unit arranged above the movable stage and configured to irradiate IPL to the semiconductor wafer. The movable IPL unit is configured to move in a second plane substantially perpendicular to the first plane. The IPL irradiation unit includes a control unit configured to control at least one of an intensity of IPL, a pulse width of IPL, a pulse gap of IPL, and a pulse number of IPL.

According to at least one example embodiment, the control unit is configured to control the intensity of IPL to be in a range of 0.01 J/cm²˜100 J/cm².

According to at least one example embodiment, the control unit is configured to control the pulse width of IPL to be in a range of 0.1 ms˜100 ms.

According to at least one example embodiment, the control unit is configured to control the pulse gap of IPL to be in a range of 0.1 ms˜100 ms.

According to at least one example embodiment, the control unit is configured to control the pulse number of IPL to be in a range of 1˜1000 times.

### BRIEF DESCRIPTION OF THE DRAWINGS

Exemplary embodiments of the inventive concepts will be more clearly understood from the following detailed description taken in conjunction with the accompanying drawings in which:

FIG. 1 is a perspective view schematically illustrating an apparatus for reducing residual stress of a semiconductor according to at least one example embodiment of the inventive concepts;

FIG. 2 is a perspective view schematically illustrating a lamp module of an IPL irradiation unit of FIG. 1;

FIG. 3 is a block diagram for describing a principle of irradiating IPL from the apparatus for reducing residual stress of a semiconductor of FIG. 1;

FIG. 4 is a flowchart illustrating a method for reducing residual stress of a semiconductor according to at least one example embodiment of the inventive concepts;

FIG. 5 is a graph showing an effect of reducing residual stress generated in a grinding process by the method for reducing residual stress of a semiconductor of FIG. 4; and

FIG. 6 is a graph showing a comparison of the flexural strengths of a semiconductor before and after the method for reducing residual stress of a semiconductor of FIG. 4 is performed.

### DETAILED DESCRIPTION OF EXAMPLE EMBODIMENTS

Exemplary embodiments of the inventive concepts are described in detail with reference to the accompanying drawings. However, the inventive concepts are not limited thereto and it will be understood that various changes in form and details may be made therein without departing from the spirit and scope of this description. That is, descriptions on particular structures or functions may be presented merely for explaining exemplary embodiments of the inventive concepts.

The terms such as “first” and “second” are used herein merely to describe a variety of constituent elements, but the constituent elements are not limited by the terms. The terms are used only for the purpose of distinguishing one constituent element from another constituent element. For example, without departing from the scope of the inventive concepts, a first constituent element may be referred to as a second constituent element, and vice versa.

In the present specification, when a constituent element “connects” or “is connected” to another constituent element, the constituent element contacts or is connected to the other constituent element directly or through at least one of other constituent elements. Conversely, when a constituent element is described to “directly connect” or to be “directly connected” to another constituent element, the constituent element should be construed to be directly connected to another constituent element without any other constituent element interposed therebetween. Other expressions, such as, “between” and “directly between”, describing the relationship between the constituent elements, may be construed in the same manner.

The terms used in this description are used for explaining example embodiments, not for limiting the inventive concepts. Thus, the expression of singularity in this description includes the expression of plurality unless clearly specified otherwise in context. Also, the terms such as “include” or “comprise” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

Unless defined otherwise, all terms used herein including technical or scientific terms have the same meanings as those generally understood by those of ordinary skill in the art to which the inventive concepts may pertain. The terms as those defined in generally used dictionaries are construed to have meanings matching that in the context of related technology and, unless clearly defined otherwise, are not construed to be ideally or excessively formal.

The attached drawings for illustrating exemplary embodiments of the inventive concepts are referred to in order to gain a sufficient understanding of the inventive concepts and the merits thereof. Hereinafter, the inventive concepts will be described in detail by explaining example embodiments of the inventive concepts with reference to the attached drawings. Like reference numerals in the drawings denote like elements.

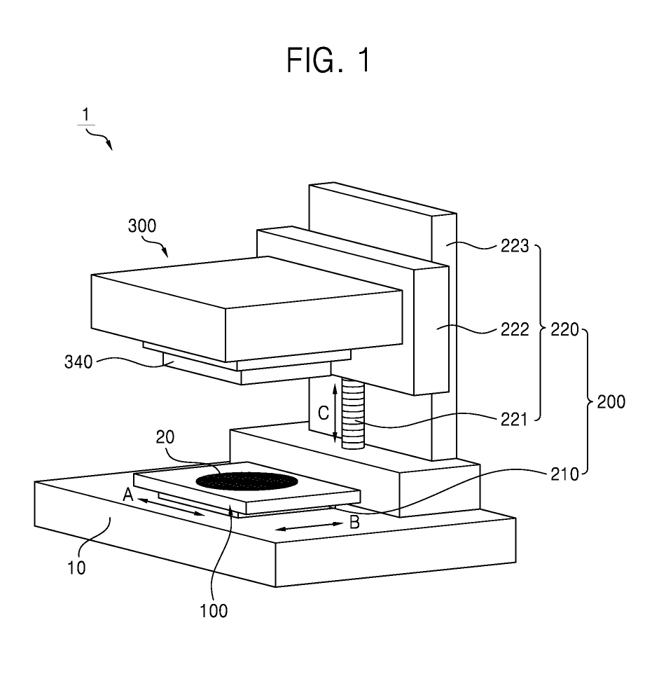

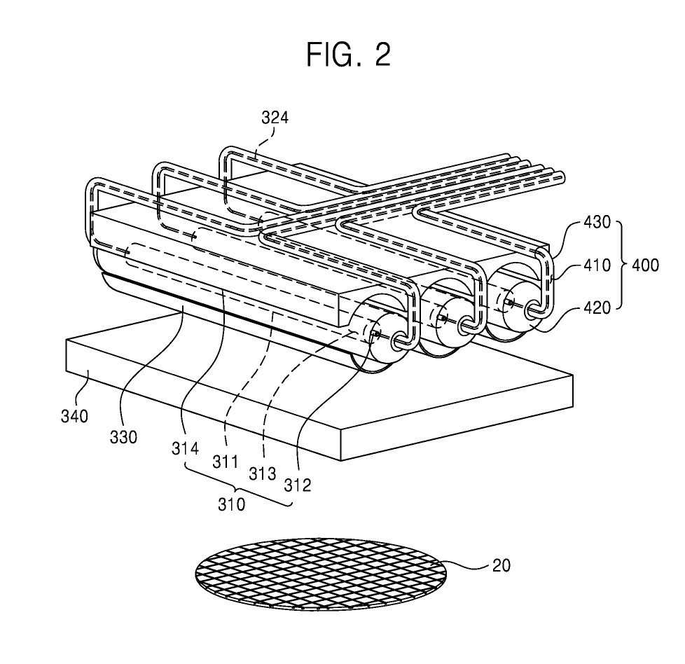

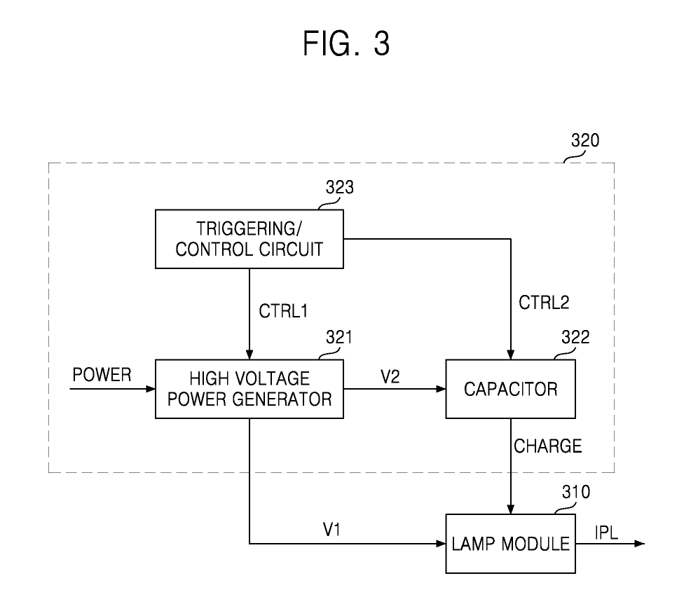

FIG. 1 is a perspective view schematically illustrating an apparatus 1 for reducing residual stress of a semiconductor according to at least one example embodiment of the inventive concepts. FIG. 2 is a perspective view schematically illustrating a lamp module of an intense pulsed light (IPL) irradiation unit of FIG. 1. FIG. 3 is a block diagram for describing a principle of irradiating IPL from the apparatus 1 for reducing residual stress of a semiconductor of FIG. 1.

As illustrated in FIGS. 1 through 3, the apparatus 1 for reducing residual stress of a semiconductor memory chip according to at least one example embodiment includes a stage 100, an alignment unit 200, an IPL irradiation unit 300, and a cooling unit 400.

The stage 100 supports a semiconductor wafer 20 undergoing a process to reduce residual stress generated in a semiconductor manufacturing process. The IPL irradiation unit 300 is arranged to be capable of approaching and being separated from the stage 100 and irradiates an IPL to reduce residual stress. The alignment unit 200 aligns relative positions of the IPL irradiation unit 300 and the semiconductor wafer 20 supported on the stage 100. The cooling unit 400 is coupled to the IPL irradiation unit 300 to reduce heat generated from the IPL irradiation unit 300.

In at least one example embodiment, the residual stress generated in a semiconductor manufacturing process may correspond to residual stress generated during a grinding process and a polishing process for thinning of the semiconductor wafer 20. However, the inventive concepts are not limited thereto and any subsequent process in which residual stress occurs may correspond to the semiconductor manufacturing process.

The stage 100 supports the semiconductor wafer 20. In at least one example embodiment, the stage 100 is coupled to a main body 10 that is capable of being moved by the alignment unit 200 relative to the main body 10. In at least one example embodiment, although the stage 100 is shown as being coupled to the main body 10, the main body 10 may be omitted if the main body 10 is not desired.

The alignment unit 200 aligns the semiconductor wafer 20 supported on the stage 100 and adjusts a relative distance between the semiconductor wafer 20 and the IPL irradiation unit 300. In at least one example embodiment, the relative distance between the semiconductor wafer 20 and the IPL irradiation unit 300 signifies a relative vertical distance between the semiconductor wafer 20 and the IPL irradiation unit 300. The alignment unit 200 includes a horizontal moving unit 210 coupled to the stage 100 to horizontally move the stage 100 and a distance adjustment unit 220 coupled to the IPL irradiation unit 300 to adjust the relative vertical distance between the stage 100 and the IPL irradiation unit 300.

The horizontal moving unit 210 is coupled to each of the main body 10 and the stage 100 and aligns the semiconductor wafer 20 with respect to the IPL irradiation unit 300 by horizontally moving the stage 100 supporting the semiconductor wafer 20 that underwent the grinding and polishing processes in a direction “A” or “B” in FIG. 1. Since the horizontal moving unit 210 may be embodied in various well-known ways, for example, a motor and a ball screw, a rack gear and a pinion gear, a pulley and a timing belt, etc., a detailed description thereof will be omitted. The horizontal moving unit 210 may be configured to move the stage 100 into a loading place out of a lower portion of the IPL irradiation unit 300 in order to load the semiconductor wafer 20 under the IPL irradiation unit 300 after the semiconductor wafer 20 is loaded on the stage 100.

The distance adjustment unit 220 is coupled to the IPL irradiation unit 300. The distance adjustment unit 220 may control the IPL irradiation unit 300 to ascend or descend to adjust the relative vertical distance between the semiconductor wafer 20 loaded on the stage 100 and the IPL irradiation unit 300. As illustrated in FIG. 1, the distance adjustment unit 220 includes a motor (not shown), a ball screw 221, a LM (linear motion) block 222, an LM guide (not shown), and a vertical frame 223. The vertical frame 223 is manufactured to support the weight of the IPL irradiation unit 300 and the LM guide may be provided inside the vertical frame 223.

The LM block 222 is coupled to the IPL irradiation unit 300. When the motor operates, the LM block 222 ascends or descends along the LM guide in a direction “C” in FIG. 1 according to a rotational direction of the ball screw 221. Accordingly, the IPL irradiation unit 300 coupled to the LM block 222 may ascend or descend.

Although the distance adjustment unit 220 is embodied in a ball-screw method, the inventive concepts are not limited thereto and a variety of methods such as a pinion gear and a rack gear or a pulley and a timing belt, etc. may be adopted.

Meanwhile, the IPL irradiation unit 300 is arranged to be capable of approaching and being separated from the stage 100. The IPL irradiation unit 300 may irradiate an intense pulsed light (IPL) onto the semiconductor wafer 20 so as to reduce residual stress of the semiconductor wafer 20. With reference to FIGS. 2 and 3, the IPL irradiation unit 300 includes a plurality of lamp modules 310, an IPL control unit 320, a light wavelength filter 330, and a beam guide 340.

The lamp module 310 irradiates an IPL and includes a lamp housing 311, an electrode 312, a xenon gas 313, and a reflective mirror 314. Although the lamp module 310 is provided in a plural number, only one lamp module may be provided if one lamp module 310 would be sufficient.

The lamp housing 311 is manufactured of a quartz material in a cylinder shape to be capable of accommodating the xenon gas 313. An electrode 312 manufactured of a metal material such as tungsten is provided at each opposite end of the lamp housing 311. The xenon gas 313 is injected into the lamp housing 311. After the xenon gas 313 is injected, the lamp housing 311 is sealed.

The reflective mirror 314 is provided outside the lamp housing 311 and reflects light that is irradiated from the lamp housing 311 in a direction opposite to the semiconductor wafer 20 to proceed toward the semiconductor wafer 20. Accordingly, an irradiation efficiency of the lamp module 310 may be improved. In other words, when the lamp housings 311 are provided in a plural number without the reflective mirror 314, IPL may be irregularly irradiated onto the semiconductor wafer 20 due to the interval between the lamp housings 311. In at least one example embodiment, however, the reflective mirror 314 may allow the IPL to be regularly irradiated.

The IPL control unit 320 is connected to the lamp module 310 and controls the generation of IPL by the lamp module 310. The IPL control unit 320 includes a high voltage power generator 321 for applying a voltage to the electrode 312, a capacitor 322 for strong charges and applying stored charges to the electrode 312, and a triggering/control circuit 323 for controlling an operation of the high voltage power generator 321 and an operation of applying the charges stored in the capacitor 322 to the electrode 312.

According to the above structure, as it is illustrated in FIG. 3, the high voltage power generator 321 generates high-voltage power and supplies the generated power to the electrode 312. In other words, after transforming an input external power POWER to a high voltage, the high voltage power generator 321 outputs a first output voltage V1 to the electrode 312 and a second output voltage V2 to the capacitor 322. The capacitor 322 receives an input of the output second voltage V2 from the high voltage power generator 321 and stores charges CHARGE, and instantly outputs the stored charges CHARGE to the electrode 312.

When the first output voltage V1 output from the high voltage power generator 321 is input to the electrode 312, discharge occurs and thus the xenon gas 313 is ionized. When the second output voltage V2 output from the high voltage power generator 321 is input to the capacitor 322, charges are stored in the capacitor 322. In this state, the charges stored in the capacitor 322 are instantly output to the electrode 312 and a current passes through the inside of the lamp housing 311, thereby exciting xenon atoms to generate light.

The triggering/control circuit 323 outputs a first control signal CTRL1 to control the operation of the high voltage power generator 321 and a second control signal CTRL2 to control the operation of outputting the charges stored in the capacitor 322 to the electrode 312.

When the capacitor 322 instantly outputs the charges stored in the capacitor 322 to the electrode 312, the triggering/control circuit 323 controls a pulse width of IPL by adjusting the length of output time, a pulse gap of IPL by adjusting an output interval, and a pulse number of IPL by adjusting the number of outputs.

The light wavelength filter 330 is provided between the lamp module 310 and the stage 100 and selectively filters light of a desired (or alternatively, predetermined) wavelength band from the IPL irradiated by the lamp module 310 so that IPL of a desired wavelength band may be irradiated onto the semiconductor wafer 20. This is because the wavelength band of IPL to effectively reduce residual stress may vary according to the type of the semiconductor wafer 20.

Although a monocrystalline silicon substrate may be used as the semiconductor wafer 20, the inventive concepts are not limited thereto and a substrate of a different type may be used.

The light wavelength filter 330 may include a plurality of light wavelength filters that filter light of a desired (or alternatively, predetermined) wavelength band. The plurality of light wavelength filters 330 may be detachably manufactured so as to be selectable according to a desired purpose. If the light wavelength filter 330 is not desired, the light wavelength filter may be omitted.

The beam guide 340 is provided between the light wavelength filter 330 and the stage 100 and guides the light passing through the light wavelength filter 330 to proceed toward the semiconductor wafer 20. The beam guide 340 protects the lamp module 310 from the outside.

The cooling unit 400 is coupled to the horizontal moving unit 210 and removes heat generated from the horizontal moving unit 210. The cooling unit 400 forms a lamp cooling unit 420 for cooling the IPL irradiation unit 300 using a coolant 410 by forming a space in which a coolant 410 flows, and a coolant flow pipe 430 connected to the lamp cooling unit 420, in which the coolant 410 circulates.

In the lamp module 310 of the IPL irradiation unit 300, since a surface of the lamp housing 311 is generally raised to a temperature of 1200 K˜1500 K during the irradiation of IPL, cooling is desired to improve the safety and lifespan of the equipment. In at least one example embodiment, the cooling unit 400 is coupled to the lamp housing 311 to directly cool the surface of the lamp housing 311. A coolant, for example, liquid or gas such as air, water, nitrogen, etc. may be used as the coolant 410.

The lamp cooling unit 420 is manufactured to surround the lamp housing 311. As the coolant 410 supplied to the lamp cooling unit 420 directly contacts the lamp cooling unit 420, the lamp housing 311 is cooled. The coolant flow pipe 430 is connected to opposite sides of the lamp cooling unit 420 and is configured to receive an input of a cool coolant at one side to cool the lamp hosing 311 and to discharge a warm coolant from the other side after cooling the lamp housing 311.

Although the figures show that an electrical wire 324 connected to the electrode 312 from the high voltage power generator 321 and that the capacitor 322 is provided inside the coolant flow pipe 430, the inventive concepts are not limited thereto. For example, only the coolant 410 may circulate in the coolant flow pipe 430.

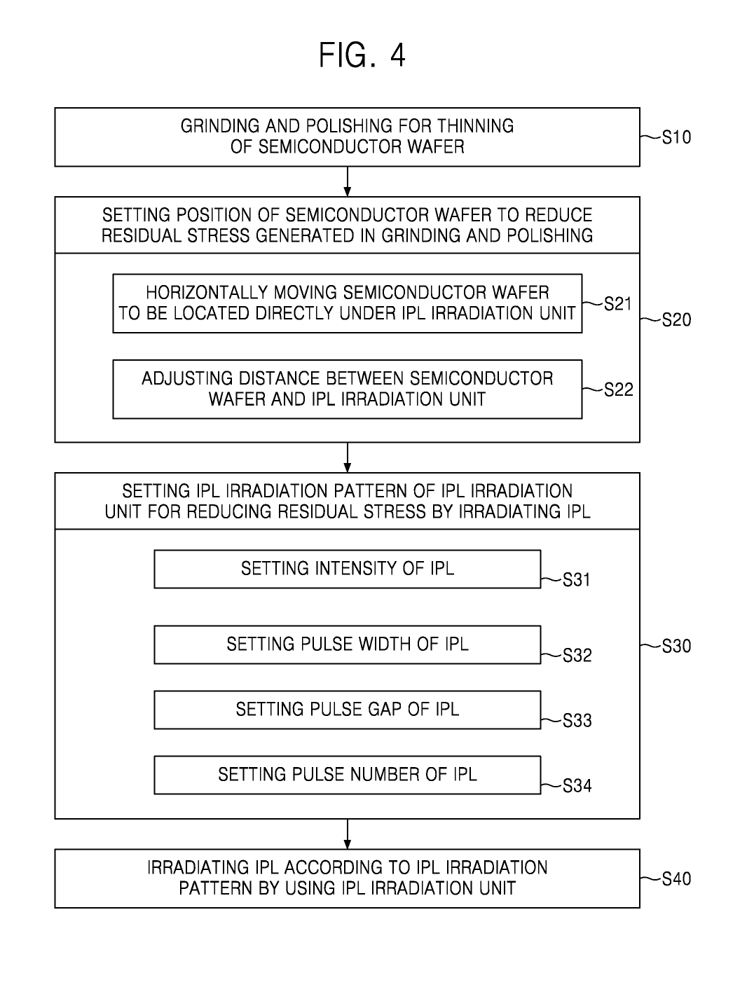

A method for reducing residual stress of a semiconductor according to at least one example embodiment of the inventive concepts is described below. FIG. 4 is a flowchart illustrating a method for reducing residual stress of a semiconductor according to at least one example embodiment of the inventive concepts.

As illustrated in FIG. 4, a method for reducing residual stress of a semiconductor includes a step S10 for thinning the semiconductor wafer 20 by grinding and polishing the semiconductor wafer 20 a step S20 for setting a position of the semiconductor wafer 20, a step S30 for setting an IPL irradiation pattern of the IPL irradiation unit 300 for reducing residual stress by irradiating IPL, and a step S40 for irradiating IPL according to the IPL irradiation pattern by using the IPL irradiation unit 300.

As described above, completion of the semiconductor manufacturing process signifies that a grinding process and a polishing process have been completed on the wafer 20. However, the inventive concepts are not limited thereto. For example, other processes that cause residual stress in the semiconductor wafer 20 may be considered as part of the semiconductor manufacturing process.

The operation of setting the position of the semiconductor wafer 20 (S20) may include horizontally moving the semiconductor wafer 20 to be located directly under the IPL irradiation unit 300 (S21), and adjusting a relative vertical distance between the semiconductor wafer 20 and the IPL irradiation unit 300 (S22). The operation of horizontally moving the semiconductor wafer 20 (S21) is performed by the horizontal moving unit 210. The operation of adjusting a relative vertical distance between the semiconductor wafer 20 and the IPL irradiation unit 300 (S22) is performed by the distance adjustment unit 220. The adjustment of a relative vertical distance between the semiconductor wafer 20 and the IPL irradiation unit 300 is desired in order to set a distance at which the irradiated IPL may be most effectively absorbed by the semiconductor wafer 20. In other words, the IPL irradiation unit 300 is raised or lowered by the distance adjustment unit 220 coupled to the IPL irradiation unit 300 to adjust the relative vertical distance between the semiconductor wafer 20 that is arranged on the stage 100 and the IPL irradiation unit 300.

In at least one example embodiment, the semiconductor wafer 20 is a monocrystalline silicon substrate. However, when a different sort of a substrate is used, the relative vertical distance between the semiconductor wafer 20 and the IPL irradiation unit 300 may be set to be different from that of the above-described exemplary embodiment. Also, since the thickness of the semiconductor wafer 20 may be manufactured to be different as necessary, the distance at which the irradiated IPL is most effectively absorbed by the semiconductor wafer 20 may be set according to the thickness of the semiconductor wafer 20 that is manufactured.

The operation of setting an IPL irradiation pattern (S30) includes setting intensity of IPL (S31), setting a pulse width of IPL (S32), setting a pulse gap of IPL (S33), and setting a pulse number of IPL (S34).

In the operation of setting intensity of IPL (S31), the intensity of IPL in the present exemplary embodiment is set in a range of 0.01 J/cm²˜100 J/cm². When the intensity of IPL is high, an annealing effect is high. However, if the intensity of IPL is greater than 100 J/cm², the semiconductor wafer 20 may be burnt. If the intensity of IPL is smaller than 0.01 J/cm², the annealing effect is degraded or does not occur at all.

In the operation of setting a pulse width of IPL (S32), the pulse width of IPL may be set in a range of 0.1 ms˜100 ms. If the pulse width of IPL is equal to or greater than 100 ms, the irradiated light is not pulsed light but continuous light and thus IPL annealing is not performed. If the pulse width of IPL is equal to or less than 0.1 ms, to irradiate light of a sufficiently high intensity within a short time, the capacitor 322 is charged with a high voltage, which may cause a problem in the safety of the capacitor 322.

In the operation of setting a pulse gap of IPL (S33), the pulse gap of IPL is set in a range of 0.1 ms˜100 ms. If the pulse gap of IPL is equal to or greater than 100 ms, the intensity of the irradiated IPL is low and thus the annealing effect does not occur. If the pulse gap of IPL is equal to or less than 0.1 ms, the irradiated light is not pulsed light but continuous light and thus IPL annealing is not performed.

In the operation of setting a pulse number of IPL (S34), the pulse number of IPL is set in a range of 1˜1000 times. When the amount of energy is fixed, the intensity of IPL decreases as the pulse number of IPL increases. Accordingly, if the pulse number of IPL exceeds 1000 times, the annealing effect may be degraded or, alternatively eliminated.

The operations of setting intensity of IPL (S31), setting a pulse width of IPL (S32), setting a pulse gap of IPL (S33), and setting a pulse number of IPL (S34) may be performed in a different order if desired.

In the operation of irradiating IPL (S40), the IPL irradiation unit 300 irradiates IPL according to an IPL irradiation pattern satisfying the intensity, pulse width, pulse gap, and pulse number of IPL that are set in the operation of setting an IPL irradiation pattern (S30).

The operation S40 is controlled by the triggering/control circuit 323 of the IPL control unit 320. When the charges stored in the capacitor 322 are instantly output to the electrode 312, the triggering/control circuit 323 controls the pulse width of IPL by adjusting the length of output time, controls the pulse gap of IPL by adjusting an output interval, and controls the pulse number of IPL by adjusting the number of outputs.

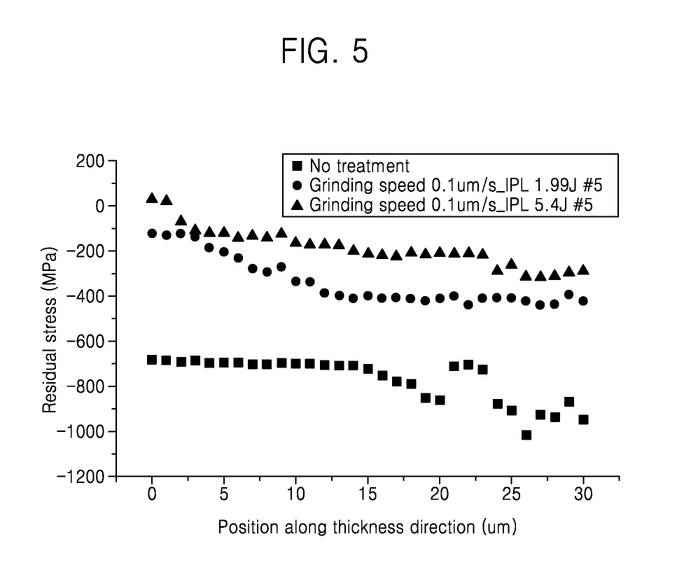

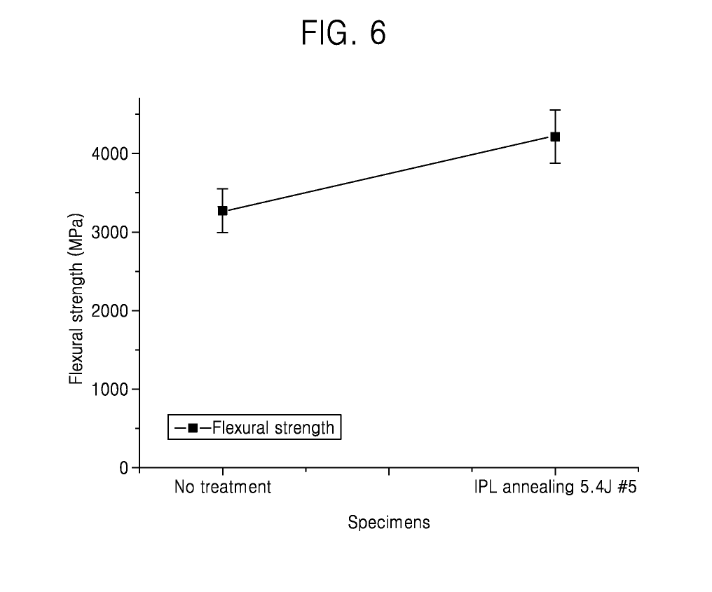

FIG. 5 is a graph showing an effect of reducing residual stress generated in a grinding process by the method for reducing residual stress of a semiconductor of FIG. 4. FIG. 6 is a graph showing a comparison of the flexural strengths of a semiconductor before and after the method for reducing residual stress of a semiconductor of FIG. 4 is performed.

Referring to FIG. 5, when IPL is not irradiated at a position 10 μm separated from a semiconductor chip along a thickness direction thereof, residual stress is about −690 MPa. When IPL of 1.99 J is irradiated, residual stress is about −320 MPa. When IPL of 5.4 J is irradiated, residual stress is about −130 MPa. Thus, the residual stress generated in the grinding process is reduced by irradiating IPL. As the amount of energy of IPL increases, an effect of reducing residual stress generated in the grinding process also increases.

Referring to FIG. 6, the flexural strength when IPL is not irradiated is about 3300 MPa. When IPL of 5.4 J is irradiated, the flexural stress is about 4200 MPa. Thus, the residual stress of a semiconductor chip is reduced by irradiating IPL so that the flexural strength of a semiconductor chip is increased.

As described above, according to the inventive concepts, the residual stress remaining in a semiconductor may be reduced at room temperature and/or in an atmospheric condition. Also, a possibility of deformation of an element on the semiconductor is low and the residual stress may be reduced in a relatively short time, thereby improving strength of the semiconductor.

While the inventive concepts have been particularly shown and described with reference to exemplary embodiments thereof, it will be understood that various changes in form and details may be made therein without departing from the spirit and scope of the following claims.

What is claimed is:

1. An apparatus for reducing residual stress of a semiconductor, the apparatus comprising:
a stage configured to support a semiconductor wafer having the residual stress generated by a semiconductor manufacturing process;
an intense pulsed light (IPL) irradiation unit configured to irradiate IPL to the semiconductor wafer to reduce the residual stress of the semiconductor wafer, the IPL radiation unit being separated from the stage; and
at least one alignment unit configured to adjust relative positions of the stage and the IPL irradiation unit.

2. The apparatus of claim 1, wherein the IPL irradiation unit comprises:
at least one lamp module irradiating IPL;
a light wavelength filter disposed between the lamp model and the stage and configured to selectively filter light of a desired wavelength band from the IPL irradiated by the lamp module;
a beam guide disposed between the light wavelength filter and the stage and configured to guide light passing through the light wavelength filter toward the semiconductor wafer; and
an IPL control unit connected to the lamp module and configured to control generation of IPL of the lamp module.

3. The apparatus of claim 2, wherein the lamp module comprises:
a lamp housing having a shape capable of containing gas;
an electrode disposed at each opposite end of the lamp housing; and
a reflective mirror disposed outside the lamp housing.

4. The apparatus of claim 3, wherein the IPL control unit comprises:
a high voltage power generator configured to apply a voltage to the electrode;
a capacitor configured to store charges and apply the stored charges to the electrode; and
a triggering/control circuit configured to control an operation of the high voltage power generator and an operation of applying the charges stored in the capacitor to the electrode.

5. The apparatus of claim 1, further comprising:
a cooling unit configured to remove heat generated in the IPL irradiation unit, wherein the cooling unit includes,
a lamp cooling unit forming a space in which a supplied coolant is movable in order to cool the IPL irradiation unit using the coolant; and
a coolant flow pipe connected to the lamp cooling unit, through which the coolant circulates.

6. The apparatus of claim 1, wherein the at least one alignment unit comprises:
a horizontal moving unit coupled to the stage and configured to horizontally move the stage; and
a distance adjustment unit coupled to the IPL irradiation unit and configured to adjust a relative vertical distance between the stage and the IPL irradiation unit.

7. The apparatus of claim 1, wherein the semiconductor process is at least one of a grinding process and a polishing process for thinning of the semiconductor wafer.

8. A method for reducing residual stress of a semiconductor, the method comprising:
setting a position of a semiconductor wafer having the residual stress generated by a semiconductor manufacturing process;
setting an intense pulsed light (IPL) irradiation pattern of an IPL irradiation unit; and
irradiating the IPL according to the IPL irradiation pattern using the IPL irradiating unit.

9. The method of claim 8, wherein the setting of a position of the semiconductor wafer comprises:
horizontally moving the semiconductor wafer to be located under the IPL irradiation unit; and
adjusting a relative vertical distance between the semiconductor wafer and the IPL irradiation unit.

10. The method of claim 8, wherein the setting of an IPL irradiation pattern comprises:
setting an intensity of IPL;
setting a pulse width of IPL;
setting a pulse gap of IPL; and
setting a pulse number of IPL.

11. The method of claim 10, wherein the setting an intensity of IPL sets the intensity of IPL in a range of 0.01 J/cm²˜100 J/cm².

12. The method of claim 10, wherein the setting of a pulse width of IPL sets the pulse width of IPL in a range of 0.1 ms˜100 ms.

13. The method of claim 10, wherein the setting of a pulse gap of IPL sets the pulse gap of IPL in a range of 0.1 ms˜100 ms.

14. The method of claim 10, wherein, the setting of a pulse number of IPL sets the pulse number of IPL in a range of 1˜1000 times.

15. The method of claim 8, further comprising:
performing at least one of grinding and polishing the semiconductor wafer prior to the setting a position of the semiconductor wafer.

16. An apparatus, comprising:
a movable stage configured to support a semiconductor wafer having residual stress caused by at least one semiconductor manufacturing process, the movable stage being configured to move in a first plane; and
a movable intense pulsed light (IPL) irradiation unit arranged above the movable stage and configured to irradiate IPL to the semiconductor wafer, the movable IPL unit being configured to move in a second plane substantially perpendicular to the first plane, the IPL irradiation unit including a control unit configured to control at least one of an intensity of IPL, a pulse width of IPL, a pulse gap of IPL, and a pulse number of IPL.

17. The apparatus of claim 16, wherein the control unit is configured to control the intensity of IPL to be in a range of 0.01 J/cm²˜100 J/cm².

18. The apparatus of claim 16, wherein the control unit is configured to control the pulse width of IPL to be in a range of 0.1 ms˜100 ms.

19. The apparatus of claim 16, wherein the control unit is configured to control the pulse gap of IPL to be in a range of 0.1 ms˜100 ms.

20. The apparatus of claim 16, wherein the control unit is configured to control the pulse number of IPL to be in a range of 1˜1000 times.
